(19) United States
(12) Patent Application Publication
(10) Pub. No.: US 2026/0319967 A1
(43) Pub. Date: Oct. 15, 2026

(54) Shared Memory Device

(71) Applicant: Graphcore Limited, Bristol (GB)

(72) Inventor: Arthur Robert Temple, Bristol (GB)

(21) Appl. No.: 19/429,025

(22) Filed: Dec. 22, 2025

(30) Foreign Application Priority Data
Apr. 9, 2025 (GB) 2505320.8

(51) Int. Cl. G06F 12/1072

(52) U.S. Cl. CPC G06F 12/1072; G06F 2212/656

(57) ABSTRACT

A shared memory device comprises output ports configured to connect to a respective client device, and memory units each having at least one egress port. Routing logic interconnects egress ports with output ports through a sequence of levels whereby a pair of egress ports are connected to each level and a final level is connected to output ports. Hardware logic receives read requests comprising a memory address from a client device, and from this identifies active and inactive memory units. Active memory units output a memory read response. Inactive memory units output a memory read response that is not responsive to any specified memory address. Hardware logic also determines and includes an identifier within each memory read response. Each memory read response is routed from an active memory unit to a desired output port based on identifiers. This provides an efficient means of multiplexing.

### TECHNICAL FIELD

The present application is related to a memory device comprising a plurality of memory read ports accessible by external devices and a plurality of memory units having respective egress ports.

### BACKGROUND

In many modern computing systems, a plurality of client devices require access to on-chip memory under strict timing and physical constraints. For example, in high-performance computing applications, multi-core parallel processing chips may be provided that include multiple individual processing units on the same physical chip. Each individual processing unit may include multiple instances of processors and/or accelerator hardware units (e.g. GPUs), along with suitable memory. In some cases, the processor and accelerator hardware each have multiple components that will need to write to and read from the memory. For example, the memory may act as a buffer for processing data.

### SUMMARY

Memory units for use in processing units of multi-core parallel processing chips – such as SRAM – are well known. In order to provide sufficient memory capacity, multiple memory units (e.g. multiple banks of SRAM) may be used, provided together as a shared memory device. A number of different “client devices” (e.g. different components of the processor(s) and accelerator hardware within the processing unit) may be connected to different ports of the shared memory device. The client devices may wish to read from different memory units in the memory device, which in some cases have independent address spaces. Accordingly, the client devices issue respective memory read requests to the shared memory device. Responsive to the memory read requests, the memory units output memory read responses comprising the requested data from the relevant memory unit. Therefore, there is a need for a suitable routing mechanism that directs the memory read responses to the appropriate memory read port to which the requesting client device is connected.

Furthermore, in some circumstances, the number of memory read ports may be less than the number of memory units in the device, and not all client devices may issue a memory read request in a particular clock cycle. Accordingly, there is a need for a memory device that can route the memory read request to an arbitrary one of the read ports of the device, effectively filtering down the output of a larger number of memory units to a smaller number of read ports.

Conventional methods involving extensive multiplexing have led to routing congestion and suboptimal wiring arrangements. Therefore, in such applications, there is a need for a mechanism that can meet the relevant timing constraints of the processing units. In other words, the memory device may be required to complete the memory reading within a single clock cycle of the processing units. Accordingly, the routing mechanism may be required to comply with these constraints. Accordingly, it may also be required to be sufficiently compact for incorporation into the processing unit. There is therefore a need for a mechanism that avoids lengthy wiring.

The disclosure addresses these issues by enabling rapid, single-cycle data routing through integrated sorting techniques that minimize the physical wiring length and limit the distance signals must travel, ultimately diminishing overhead and mitigating path delays. The architecture is especially well-suited for compact layouts where multiple clients cannot all be placed adjacent to every memory bank.

According to a first aspect of the disclosure, there is provided a shared memory device, comprising:
a plurality of output ports, each output port configured for connection to a respective client device of a plurality of client devices;
a plurality of memory units, each memory unit comprising at least one egress port, wherein the number of egress ports comprised by the plurality of memory units is greater than or equal to the number of output ports;
routing logic connecting the egress ports to the output ports;
hardware logic configured to:
   receive at least one read request from a client device of the plurality of client devices, each read request comprising a memory address in one of the memory units;
   identify each memory unit comprising a memory address that is present in a received read request as an active memory unit, and identify each memory unit not storing any memory address present in a received read request as an inactive memory unit;
   cause each active memory unit to output, via its respective egress port, a memory read response comprising data stored at the memory address, and cause each inactive memory unit to output, via its respective egress port, a memory read response that is not responsive to any memory address specified in a received read request;
   determine an identifier for each memory read response, wherein an identifier for a memory read response from an active memory units is based on a desired output port for that memory read response;
   include the identifier in each memory read response;
   provide each memory read response to the routing logic;
wherein the routing logic comprises a plurality of levels, a pair of egress ports being connected to each level of the plurality of levels;
wherein the routing logic is configured to route each memory read response from an active memory unit to a respective desired output port based on the identifiers.

Each level of the routing logic may comprise at least one swap block comprising first and second inputs and first and second outputs. The swap block may be configured to receive a first memory read response and a second memory read response at the first and second inputs respectively. The swap block may be configured to compare the identifier of the first memory read response with the identifier of the second memory read response. The swap block may be configured to, in response to the identifier of the first memory read response being greater than the identifier of the second memory read response, output the first memory read response via the first output and the second memory read response via the second output. The swap block may be configured to otherwise output the first memory read response via the second output and the second memory read response via the first output. By otherwise, it may be meant in response to the identifier of the first memory read response being less than or equal to the identifier of the second memory read response. Each swap block may comprise a multiplexer. The multiplexer may be configured to receive a swap signal that indicates whether or not to swap the first memory read response and second memory read response. The swap block may comprise a comparator, configured to compare the identifiers of the first and second memory read responses and generate the swap signal.

The hardware logic of the shared memory device may determine an identifier for each memory read response comprising data stored at the respective memory address that is equal to or otherwise corresponds to an identifier of the desired output port. The identifier may reflect a physical position of the desired output port.

The hardware logic may determine, for any memory read response from an inactive memory unit, an identifier that corresponds to an unused output port or a dummy output port. The memory read

response emanating from an inactive memory unit may comprise data read in a previous cycle, suitably from the last cycle in which the inactive memory unit was active. The memory read response emanating from an inactive memory unit may comprise uninitialized data.

The identifier may be a unique integer in the range 0 to n-1, where n may be the number of egress ports.

The hardware logic of the shared memory device may be configured to remove the identifier from the memory read response before it egresses via the output port.

The memory units of the shared memory device may be arranged in two columns. The pair of egress ports connected to a level of the sequence of levels may have corresponding positions in respective ones of the two columns. The routing logic may be disposed between the two columns.

Each level of the routing logic may be disposed between the pair of egress ports to which it is connected. Accordingly, the pair of memory units associated with a particular level may be disposed on either side of the layer.

The shared memory device may be configured to receive the at least one read request and determine the identifiers in a first clock cycle, and cause the memory units to output the memory read responses, provide the memory read responses to the routing logic and route the or each memory response comprising data to the desired output port in a second clock cycle. The second clock cycle may be immediately after the first clock cycle.

Each memory unit of the shared memory device may be a bank of static random access memory, SRAM. Each memory unit may be implemented as an array of flip-flops, a storage cell (e.g. a 6T, 10T or any other storage cell), or by using latches.

The read request may explicitly identify one of the memory units comprising the memory address. In other examples, the memory controller may infer the relevant memory unit.

The read request may comprise data identifying the output port to which it is to be directed. In other examples, this may be inferred from the context.

According to a second aspect of the disclosure, there is provided a processing unit comprising a shared memory device as defined in the first aspect and accelerator hardware having multiple subcomponents, each subcomponent acting as a client device of the shared memory device.

The shared memory device may act as a buffer configured to store data on which operations are performed by the accelerator hardware.

The accelerator hardware may comprise hardware designed specifically for carrying out operations in neural network processing, graphics processing or any other suitable processing.

The accelerator hardware may not be a processor in the sense that it does not have the ability to independently execute code but instead may operate under the control of processor hardware.

Further optional features of the second aspect are defined hereinabove in relation to the first aspect, and may be combined in any combination.

According to a third aspect of the disclosure, there is provided a processor comprising a plurality of processing units as defined in the second aspect.

Further optional features of the third aspect are defined hereinabove in relation to the first aspect and second aspect, and may be combined in any combination.

According to a fourth aspect of the disclosure, there is provided a method carried out in a shared memory device, the shared memory device comprising:
a plurality of output ports, each output port connected to a respective client device of a plurality of client devices;
a plurality of memory units, each memory unit comprising at least one egress port, wherein the number of egress ports comprised by the plurality of memory units is greater than or equal to the number of output ports;
routing logic connecting the egress ports to the output ports;
the method comprising:
receiving at least one read request from a client device of the plurality of client devices, each read request comprising a memory address in one of the memory units;
identifying each memory unit storing a memory address that is present in a received read request as an active memory unit, and identifying each memory unit not storing any memory address present in a received read request as an inactive memory unit;
causing each active memory unit to output, via its respective egress port, a memory read response comprising data stored at the memory address, and causing each inactive memory unit to output, via its respective egress port, a memory read response that is not responsive to any memory address specified in a received read request;
determining an identifier for each memory read response, wherein an identifier for a memory read response from an active memory unit is based on a desired output port for that memory read response;
including the identifier in each memory read response;
providing each memory read response to the routing logic;
routing, by the routing logic, each memory read response from an active memory unit to a respective desired output port based on the identifiers; wherein the routing logic comprises a sequence of levels, a pair of egress ports being connected to each level, a final level in the sequence being connected to the output ports, each other level in the sequence providing input to a subsequent level of the sequence

Further optional features of the method of the fourth aspect are defined hereinabove in relation to the first, second and third aspect, and may be combined in any combination.

According to a fifth aspect of the disclosure, there is provided a computer program product comprising instructions in a hardware description language, which when executed by a computer, cause the computer to generate data representing hardware circuitry that implements any of the logic described herein. The data representing the hardware circuitry may comprise a netlist. The computer program product may be executable by a synthesis tool executable on the computer. The instructions may be in Verilog.

According to a sixth aspect of the disclosure, there is provided a computer readable medium storing the computer program product of the fifth aspect. Suitably, the computer readable medium is non-transitory.

### BRIEF DESCRIPTION OF DRAWINGS

For a better understanding of the present invention to show how the same may be carried into effect, reference will now be made by way of example to the accompanying drawings:

FIG. 1 is a schematic block diagram of an example environment comprising a host system and processor.

FIG. 2 is a schematic block diagram of an example processing unit.

FIG. 3 is a schematic block diagram of an example shared memory device.

FIG. 4 is a schematic block diagram showing the memory units and routing logic of an example shared memory device in more detail.

FIG. 5 is a schematic block diagram showing the routing logic of an example shared memory device in more detail.

FIG. 6 is a schematic block diagram of an example swap block included in a shared memory device.

FIG. 7 is a schematic flowchart of an example process of assigning identifiers to memory read responses.

FIG. 8 is a schematic block diagram of an example read request.

FIG. 9 is a schematic block diagram of an example read response.

FIG. 10 is a schematic block diagram of an example shared memory device comprising two-port memory units.

In the drawings, corresponding reference characters indicate corresponding components. The elements in the figures are illustrated for simplicity and clarity and have not necessarily been drawn to scale. For example, the dimensions of some of the elements in the figures may be exaggerated relative to other elements to help to improve understanding of various examples. Also, common but well-understood elements that are useful or necessary in a commercially feasible example are often not depicted in order to facilitate a less obstructed view of these various examples.

### DETAILED DESCRIPTION

In overview, examples of the disclosure provide a shared memory device configured to route data from a plurality of memory units (e.g. RAM banks), to a number of memory read ports that is either the same as or smaller than the number of memory units. The shared memory device is sometimes referred as a shared buffer unit (SBU), on account of its application as a buffer for client devices.

In examples, routing logic in the form of a sorting tree structure is employed. Memory read responses are assigned an identifier (also referred to herein as an index) by an indexing mechanism based on the memory read port that they are destined for. They are then subsequently routed through a series of swap blocks. This arrangement provides an efficient means of managing multiple memory read responses within a single clock cycle, while also reducing routing congestion. Memory units not being read from may be caused to output “dummy” read responses that are also input to the sorting tree, which are also assigned identifiers. In this context, the dummy read responses may comprise whatever the read data was last time the memory unit was read from, or in the event that the process is occurring just after reset, some uninitialized (and so undefined) data.Any unused outputs (i.e. the memory read responses output by memory units not responsive to an input memory read request) are discarded by the routing logic without interfering with active reads.

In examples, at the architectural level, the shared memory device comprises multiple memory banks arranged in an ordered configuration accompanied by routing logic that features a series of swap blocks. Each swap block consists of two data inputs and two data outputs and is designed to compare the identifiers of incoming data packages to determine whether a swap is needed. A higher identifier is directed to one side while a lower identifier is shifted to the opposite side. This pairwise sorting mechanism can be repeated across multiple levels, creating a multi-level routing tree that remains physically efficient and scales with various RAM bank and port counts.

In examples, the indexing mechanism assigns each memory read response an identifier that reflects the physical position of the desired output port. When a client device issues a read request, the routing logic determines the appropriate identifier for the memory read response and adjusts the identifiers of other responses. This dynamic assignment of identifiers permits the correct read responses to be directed to the desired output ports, and caters for situations in which multiple requests are directed to different memory units destined for different output ports in the same clock cycle.

In examples, implementation of the swap blocks is achieved through physical multiplexers that use a one-bit swap signal to determine whether read responses should be exchanged. The swap signal is determined based on comparison of the indices of the read responses. This hardware-based approach ensures that the routing of memory read responses meets the stringent timing constraints. The modular nature of each swap block also allows for simple replication of these elements in larger designs.

In examples, pairs of the memory units feed into each level of the routing logic. Accordingly, the physical location of the memory units may be aligned with the routing logic. That is to say each pair of memory units can be positioned proximate to their associated level of the routing logic. For example, the memory units may be disposed in two columns and the routing logic disposed between the columns. Accordingly, the pair of memory units associated with a particular level may be disposed on either side of the layer. The disclosure therefore effectively addresses both silicon space limitations and the necessity for rapid, nearest neighbour connections, ensuring efficient memory read operations without extraneous design complexity. This physically aware layout further helps maintain short wire lengths.

The disclosure supports varying numbers of memory units. So long as the number of memory units (or rather the egress ports of the memory units) exceeds or matches the number of read ports, the techniques can flexibly discard extra outputs. In a representative example with ten banks and six read ports, four outputs are filtered and discarded, ensuring that only the actively addressed banks appear at the read ports at the end of each cycle.

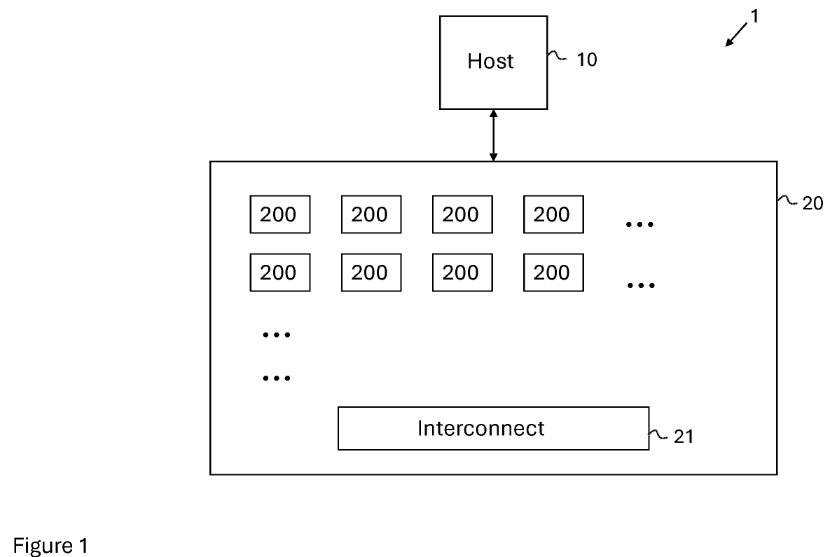

FIG. 1 illustrates an environment 1 in which examples of the disclosure may operate. The environment comprises processor 20, which in turn comprises a plurality of processing units 200.

This processor 20 is a subsystem that is configured to act as a work accelerator for a host system 10. The subsystem acts as an accelerator to perform predetermined processing steps on data sets (work) allocated by the host 10, which may be running a process requiring large amounts of data to be subject to mainly repetitive processing. The subsystem 20 may be a so called intelligence processing unit (IPU) or any class of accelerator (XPU). The techniques described herein can be used with the IPUs described in our earlier U.S. application Ser. No. 15/885,925, the contents of which are herein incorporated by reference, but also can be applied to any accelerator.

For convenience, given that the focus is a component of a processing unit 200 of the processor 20, the discussion herein relates to a single processor 20. However, in practice, several processors 20 may be combined to form an accelerator machine or appliance. Several accelerator appliances may be combined in a chassis. Multiple chassis may be organised in groups, which can be arranged in a rack. The resulting combinations of accelerators can yield a system with a large amount of processing power for performing parallel operations. This is particularly useful for implementing neural network processing in artificial intelligence applications. The principles laid out here can potentially be used to scale beyond a single rack as well.

Each accelerator may be a single chip processor. FIG. 1 shows a single chip processor 20, i.e. a single die, comprising an array of multiple processor tiles 200 and an on-chip interconnect 21 connecting between the tiles 200. The chip 20 may be implemented alone on its own single-chip integrated circuit package, or as one of multiple dies packaged in the same IC package. The on-chip interconnect may also be referred to herein as the “exchange fabric” 21 as it enables the tiles 200 to exchange data with one another. Each tile 200 is a processing unit capable of executing instructions (code) from a local instruction memory and handling data in local data memory. For instance, by way of illustration the chip 20 may comprise of the order of hundreds of tiles 200, or even over a thousand. For completeness, note also that an “array” as referred to herein does not necessarily imply any particular number of dimensions or physical layout of the tiles 200. Furthermore, the term “tile” used herein is not a reference to a particular type of processing hardware or unit, and is not intended to be limiting as to the particular components of the processing unit 200.

The chip 20 also comprises one or more external links (not shown), enabling the chip 20 to be connected to one or more other, external processors on different chips (e.g. one or more other instances of the same chip 20). These external links may act as chip-to-chip links for connecting together with one or more other instances of the chip 2 on the same IC package or card, or on different cards. Multiple instances of the chip 20 can be connected together into cards by chip-to-chip links. The external links also include a suitable external link for communicating with host system 10, such as a PCIe interface. In some examples, the host system 10 and processor 20 are co-located – e.g. the processor 20 and host 10 are disposed in the same machine or chassis. However, in other examples, the host system 10 may be disposed remotely from the processor 20 and the connection therebetween encompasses network connections such as local and/or wide area connections, including the internet.

The interconnect 21 is configured to enable the different processor tiles 200 to communicate with one another on-chip 20. In the IPU described in our earlier patent applications, communication between tiles 200 on the accelerator 20 occurs in a time deterministic fashion. However, other forms of inter tile exchange are possible. There may be dependencies between the portions of the program running on different tiles 200. That is, processing data on one tile may depend on results from another tile, e.g. may provide results on which another tile depends. A technique may therefore be required to prevent a piece of code on one tile 200 running ahead of data upon which it is dependent being made available by another piece of code on another tile 200.

Parallel programming models for AI and Data Science usually follow a 3-phase iterative execution model: Compute, Barrier, and Exchange. The implications are that data transfer to and from an accelerator is usually barrier dependent to provide data-consistency between the accelerators and between each accelerator and the host. Typically used data consistency models are Bulk Synchronous Parallel (BSP), Stale Synchronous Parallel (SSP) and Asynchronous. In SSP, the faster worker thread of a plurality of worker threads is allowed to run ahead of the slowest worker thread by a number of clock cycles. A worker thread is able to see updates made to a shared parameter having a range of time stamps. For example, a worker at clock t is able to see all updates from workers up to those updates that are timestamped at t−Δ. BSP is a special case where Δ=0 and therefore the workers may not run ahead of each other.

Accordingly, in some examples, the processor 20 employs a BSP model but, but it will be apparent that the other synch models could be utilised as an alternative.

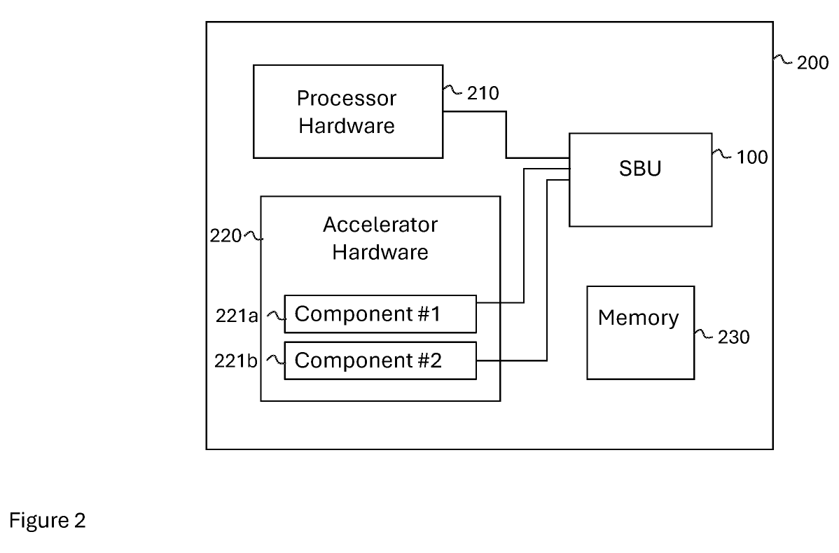

FIG. 2 shows an example architecture of a processing unit 200. The processing unit 200 may include processor hardware 210, accelerator hardware 220, and a memory 230. The processing unit 200 also includes a shared buffer unit (SBU) 100, which is an example of a shared memory device in accordance with examples of the disclosure.

The processor hardware 210 may take the form of any suitable processor hardware configured to execute instructions stored in memory 230. The instructions may cause the processor hardware to perform operations on data also stored in memory 230.

The accelerator hardware 220 may take the form of any suitable accelerator hardware configured for accelerated processing. For example, the accelerator hardware may comprise hardware designed specifically for carrying out operations in neural network processing, graphics processing or any other suitable processing. In examples, the accelerator hardware 220 is not a processor in the sense that it does not have the ability to independently execute code but instead operates under the control of processor hardware 210. For example, the accelerator hardware 220 may be configured to perform operations on data held in the SBU 100. Accordingly, the SBU 100 is a buffer in the sense that it provides temporary storage for data on which the operations are performed.

The accelerator hardware 220 may comprise a plurality of subcomponents 221, which may access the SBU 100, by both reading from and writing to the SBU. Reference numbers 221a and 221b illustrate two such subcomponents, but in reality, the accelerator hardware 220 may have a larger number (e.g. 6) of subcomponents 221. Furthermore, the processor hardware 210 may also access the SBU 100.

The accelerator hardware 220 and/or processor hardware 210 are examples of “client devices” that may be connected to the SBU 100 in order to interact therewith. The client devices are configured to issue memory write requests to the SBU 100, to cause writing of data to the SBU 100. Herein, conventional mechanisms for writing to memory such as the SBU 100 are employed and thus not discussed in detail further.

Furthermore, the client devices are configured to issue memory read requests to the SBU 100, specifying data, or more particularly the addresses of data, to be retrieved from the SBU 100. Receipt of a memory read request causes the SBU 100 to return memory read responses (also termed “completions”) comprising the specified data. The structure of the read requests and read responses will be discussed further below.

The example shown in FIG. 2 is one example of an architecture of a processing unit 200. In other examples, the processing unit 200 may omit the processor hardware 210, or may include multiple instances of the accelerator hardware 220 or may otherwise be differently configured.

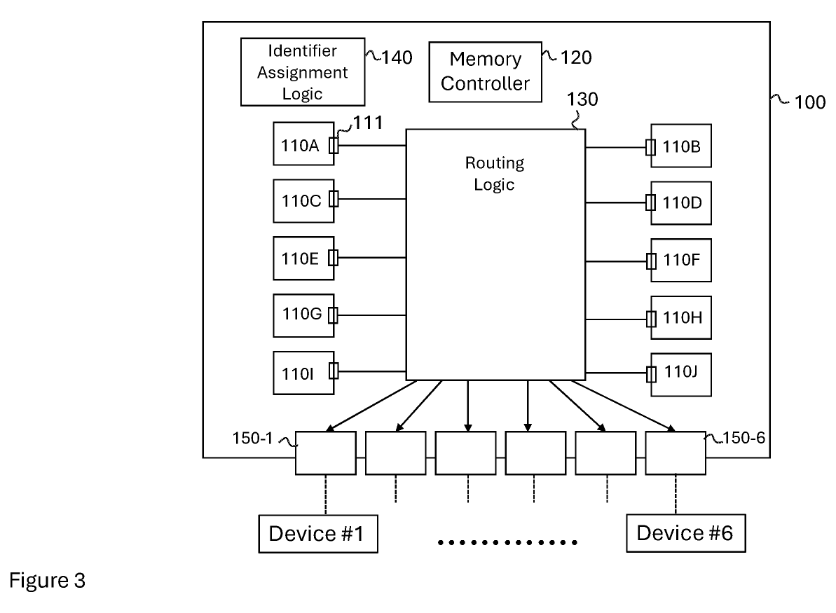

FIG. 3 is a schematic representation of the architecture of the SBU 100. The SBU 100 comprises a plurality of memory units 110A-110J, a memory controller 120, routing logic 130, identifier assignment logic 140 and a plurality of output ports 150.

The memory units 110 each comprise suitable memory. For example, each memory unit may comprise SRAM. In one example, each memory unit may have 512 entries (i.e. storage regions) each having a size of 512 bits, giving a total capacity of 256 kilobits or 32 kilobytes per memory unit. The memory unit 110 may be implemented as an array of flip-flops, a storage cell (e.g. a 6T, 10T or any other storage cell), or by using latches. Each of the memory units 110 has a respective egress port 111, through which memory read responses egress the memory unit 110. It will be appreciated that, although not shown, each memory unit may comprise further ports for receiving write requests and read requests. In this example, the SBU 100 comprises ten memory units 110A-J.

The memory controller 120 is configured to receive read requests from client devices 210, 221.

The read requests comprise data identifying a memory address comprised in one of the memory units 110. In addition, the read requests may explicitly identify one of the memory units 110 comprising the memory address. However, in other examples, the memory controller 120 may infer the relevant memory unit – for example, where one particular client device only interacts with one of the memory units 110, it may be inferred that that memory unit 110 is the one being accessed by the read request.

In some examples, the read requests also comprise data identifying the output port 150 to which it is to be directed. However, in other examples, this may likewise be inferred from the context. For example, the read request may comprise data identifying the client device issuing the request, from which the relevant port 150 can be straightforwardly determined.

In response to received read requests, the memory controller 120 causes the memory units 110 to output read responses comprising the requested data stored in the specified memory addresses. In addition, other memory units 110 that are not being read from (i.e. that do not correspond to a memory unit 110 indicated in a received read request) are also caused to output “dummy” read responses. The memory units 110 not being read from may be termed “inactive” memory units, with the memory units 110 that are being read from being termed “active” memory units.

The dummy read responses may for example include the data read responsive to a previous read request, such as in an earlier clock cycle. In other words, it may be convenient to cause the memory unit 110 to simply output the same data it last output. In other examples, it may be the case that the dummy data is some uninitialised or undefined data. This may be the case where the system has been recently reset and so there is no previously read data to output. It will be appreciated that there are various options for causing the inactive memory units 110 to provide suitable output.

The dummy read responses comprise data that will not be supplied to a client device 210, 221. Instead, the dummy read responses are merely used in the routing logic 130 as discussed below.

The memory controller 120 is further configured to trigger the identifier assignment logic 140. The identifier assignment logic 140 is configured to include an identifier in the memory read responses emanating from the memory units 110. The identifiers are integers, to facilitate a numeric comparison thereof in the routing logic. Particularly, the identifiers are a values from 0 to n-1, where n is the number of memory units 110.

The routing logic 130 is configured to route the memory read responses (including the dummy responses) having the identifiers, such that memory read responses to a desired output port 150 of the output ports.

The output ports 150 are connected to respective client devices 210, 221. In this example, six output ports 150 are provided for connection to six client devices.

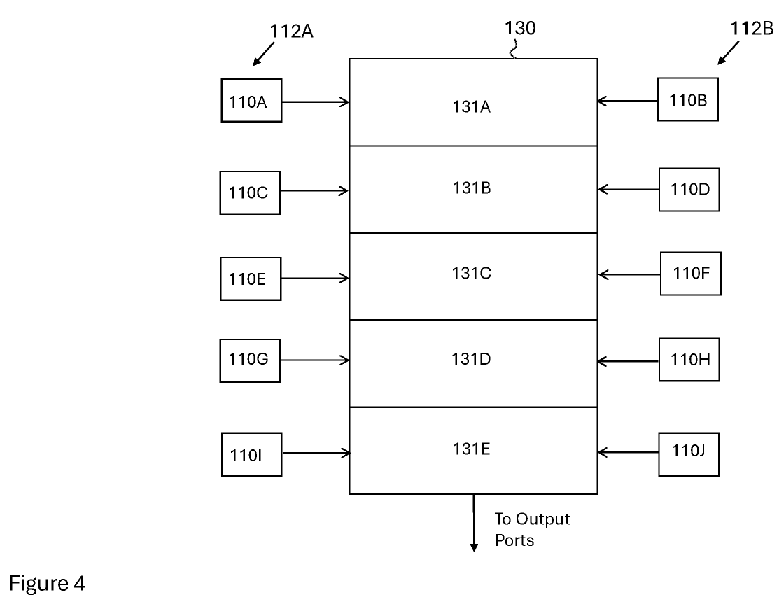

FIG. 4 illustrates the configuration of the memory units 110 and routing logic 130 in further detail. Although the view is schematic, it is intended to reflect (at least to some extent) the physical disposition of the components of the device 100.

As illustrated in FIG. 4, the memory units 110 are arranged in two columns 112A-B of equal length, and thus each comprising five of the memory units 110. The routing logic 130 is generally disposed between the two columns 112. The routing logic comprises a plurality of levels 131A-E. Each level 131A-D provides output to the subsequent level, with final level 131E being connected to the output ports.

Each level 131 is furthermore connected to two memory units 110. Particularly, each level 131 is connected to a pair of memory units 110 having corresponding positions in their respective columns. The pair of memory units 110 to which a level 131 is connected are those most proximate to the pair of memory units 110. In other words, memory units 110 disposed opposite one another in the columns 112 are connected to the level 131 therebetween. Accordingly, memory units 110A, 110B form a pair connected level 131A, memory units 110C, 110D form a pair connected to level 131B, and so on through to memory units 110I, 110J connected to fifth level 131E.

As will be apparent from the discussion further below, this structure of the routing logic 130 allows the memory units 110 to inputs to different levels of the sorting tree embodied in routing logic 130, thus progressively inputting the memory read responses. Accordingly, the routing logic 130 is “physically aware” – i.e. the routing logic 130 is designed and configured such that the physical locations of the memory units 110 are taken into account. This mechanism enables compact layout and facilitates short “nearest neighbour” links as illustrated in FIG. 4.

It will be appreciated that this is merely one example layout that gives rise to such advantages – for example, the memory units 110 may be arranged in a single column or some other layout, so long as pairs of memory units can be connected by relatively short connections to respective levels of the routing logic 130.

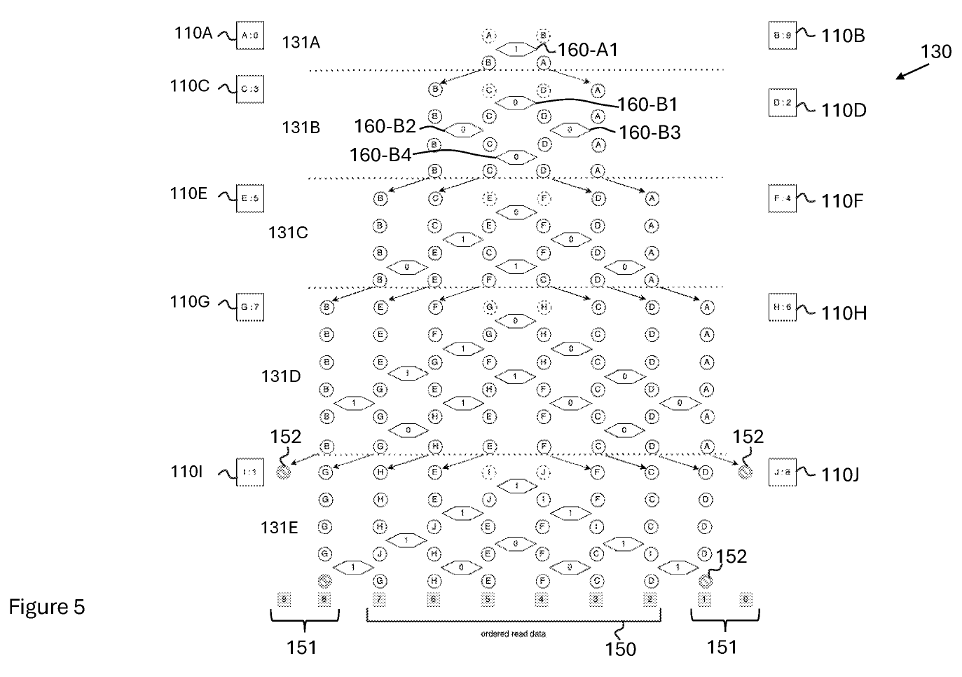

Turning to FIG. 5, the routing logic 130 is displayed in further detail, in logical form. Each layer 131A-E comprises at least one swap block 160. Not all swap blocks in the figure are labelled to facilitate a clearer view of routing logic 130.

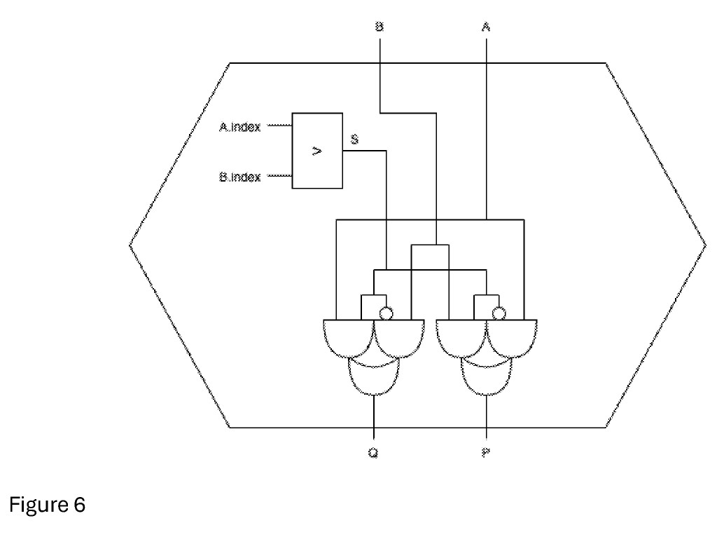

FIG. 6 shows an example swap block 160 in detail. The swap block 160 takes two input memory read responses (labelled as A and B), and can selectively perform one of two operations. Firstly, it can act as a pass-through, thereby outputting the read response received at A at corresponding output P and the read response received at B at corresponding output Q. Alternatively, as the name swap block 160 suggests, the block 160 can swap the order of the two responses, such that A outputs to Q and B outputs to P.

Whether the swap block 160 swaps the responses or passes them through is based on a control signal S. The control signal may be binary. For example, 0 may indicate that the swap block 160 passes the responses through, and 1 may indicate that the swap block 160 swaps the responses. The control signal S is generated by the swap block 160 based on a comparison of the identifiers of the read responses. If the identifier of input A is greater than the identifier of input B, the read responses are passed through. Otherwise, the responses are swapped.

Returning to FIG. 5, dotted circles represent where read responses feed into the routing logic 130 from the respective memory units 110. For example, the dotted circle A shows the initial position of the output of memory unit 110A. Furthermore, also displayed on FIG. 5 is the identifier assigned to a read response emanating from a particular memory unit 110. For example, memory unit 110A is assigned identifier 0, memory unit 110B is assigned identifier 9, and so on.

The first level 131A is configured to receive as input read responses from memory units 110A and 110B, which are input to a first swap block 160-A1. As the identifier 0 of the read response emanating from memory unit 110A is not greater than the identifier 9 of the read response emanating from memory unit 110B, the responses are swapped.

The second level 131B comprises four swap blocks 160-B1 to 160-B4. The first swap block 160-B1 of the second level 131B receives input read responses from memory units 110C and 110D, respectively having identifiers 3 and 2. As 3 is greater than 2, the responses are passed through. Subsequent swap blocks 160-B2 and 160-B3 form a second layer within the level 131B, and each receive as input a read response from swap block 160-A1 and a read response from swap block 160-B1. Finally in third layer of the level 131B, swap block 160-B4 receives input from swap blocks 160-B2 and 160-B3.

The third level 131C receives input from memory units 110E and 110F, and comprises another three layers of swap blocks 160-C. The pattern of multiple swap blocks per level, with a new pair of memory units feeding in at each level continues throughout the remaining levels 131D and 131E.

The routing logic 130 shuffles the read responses emanating from the memory units 110 based on the identifiers, so that the read response arrives at an output port 150 corresponding to its identifier. Furthermore, as there are more read responses than available ports 150, some identifiers are assigned to “dummy” ports, indicated by reference numeral 151, and discarded as indicated by icons 152. These dummy ports may be disposed laterally outside of the location of the active ports 150, so that the unwanted responses are shuffled outwards by the swap blocks 160.

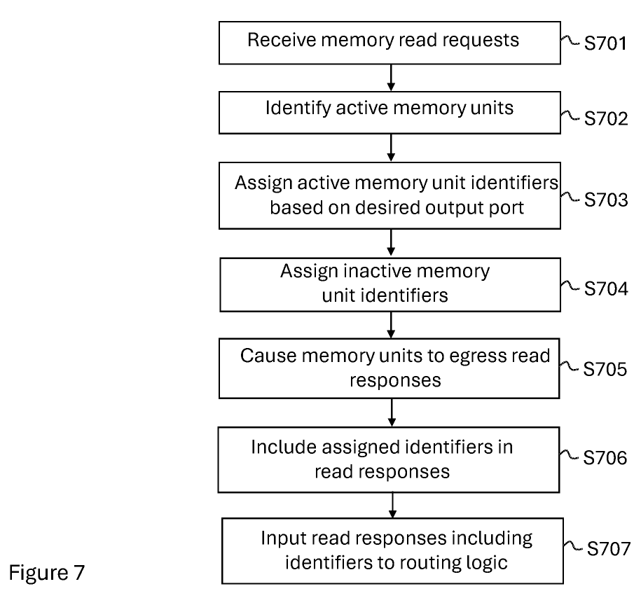

FIG. 7 illustrates the process by which identifiers are assigned to the memory units 110 or more specifically the read responses emanating from the memory units 110. The process may be carried out by identifier assignment logic 140 in conjunction with memory controller 120.

In a first step S701, at least one memory read request is received by memory controller 120. Each request comprises a memory address and either implicitly or explicitly indicates the memory unit 110 comprising the memory address. Furthermore, the memory read request also implicitly or explicitly indicates the output port 150 to which the memory read response should be routed, so that it can be subsequently returned to the relevant client device.

In a second step S702, the identifier assignment logic 140 identifies, based on the received read requests, which memory units 110 have received read requests that pertain to them. The memory units 110 indicated in received read requests are termed the “active” memory units 110. The memory units 110 that are not amongst the memory units indicated in the received read requests are “inactive” memory units.

In a third step S703, the identifier assignment logic 140 assigns each active memory unit 110 an identifier that corresponds to the desired output port 150. Briefly returning to FIG. 5, the position of the output ports 150 and dummy ports 151 are indicated by values 0-9, which are reflective of their ordered position from right to left. The six output ports 150 occupy positions 2-7. Accordingly, a memory read request specifying that the output of memory unit 110E should be routed to position 5 of the output ports 150 results in the memory unit 110E being assigned the identifier 5. The positions can be thought of as identifiers of the output ports

In a fourth step S704, the identifier assignment logic 140 also assigns each inactive memory unit an identifier. These identifiers correspond to either the dummy ports 151 or ones of the output ports 150 that are not being read from in a particular clock cycle. In other words, if a client device is connected to a particular port 150 but does not issue a read request, that port can effectively be treated as a dummy port. In one example, the remaining identifiers not assigned to active memory units are assigned to the inactive memory units in ascending order.

The identifiers assigned in the above process are unique. That is to say, no two memory units 110 may have the same identifier. Furthermore, all of the memory units 110 are assigned an identifier, regardless of whether they are being read from in a cycle.

In a fifth step S705, the memory controller 120 causes the active banks to egress memory read responses comprising the data stored at the memory addresses included in the respective read requests. Furthermore, the memory controller causes the inactive banks to output a dummy memory read response comprising no data.

In a sixth step S706, the identifier assignment logic 140 includes the assigned identifiers in the memory read responses, before they are input to the routing logic. For example, each read response may take the form of a packet, wherein a field of the packet (e.g. a header or footer) includes the identifier.

In a seventh step S707, the memory read responses including the identifiers are input to the routing logic 130, in the manner set out above. The routing logic 130 delivers the memory read responses from the active memory units 110 to their desired output ports 150. Before egress of the read responses from the SBU 100, the identifiers may be removed from the memory read responses. This is because the identifier has by this time served its purpose of directing the read response to the correct output port 150.

The steps that involve receiving the read requests and determining the assignment of identifiers may be carried out in one clock cycle, with the steps of including the identifiers in the responses and sorting the responses through the routing logic taking place in the next clock cycle.

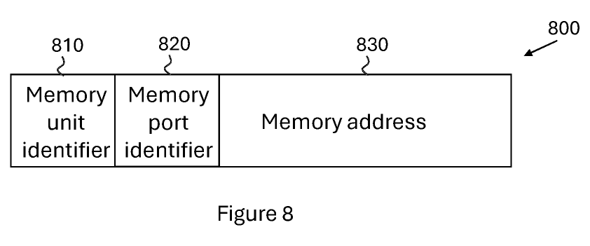

FIG. 8 illustrates an example of read request 800 comprising a memory address 830 comprising data identifying a memory address in one of the memory units 110, a memory unit identifier 810 identifying one of the memory units 110 comprising the memory address, and a memory output port identifier 820 comprising data identifying the output port 150 to which it is to be directed.

In other examples, rather than the read request 800 explicitly identifying the memory unit 110 comprising the memory address, the memory controller 120 may infer the relevant memory unit 110. In other examples, rather than the read request 800 comprising data identifying the output port 150 to which it is to be directed, the output port 150 may be inferred from the context.

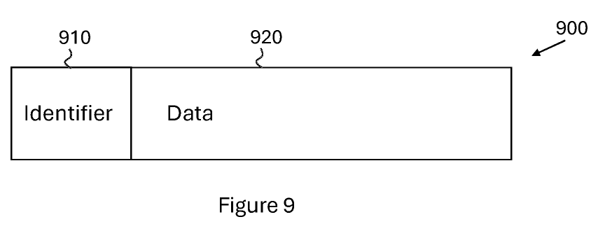

FIG. 9 illustrates an example of a read response 900 comprising the requested data 920 and an identifier 910 that reflects the physical position of the desired output port for the read response 900. Each read response 900 may take the form of a packet, wherein a field of the packet (e.g. a header or footer) includes the identifier 910. The identifier 910 is assigned by the identifier assignment logic 140, and may be removed before the read response 900 exits the SBU 100.

Dummy read responses may comprise whatever the read data 920 was last time the memory unit 110 was read from, or in the event that the process is occurring just after reset, some uninitialised (and so undefined) data.

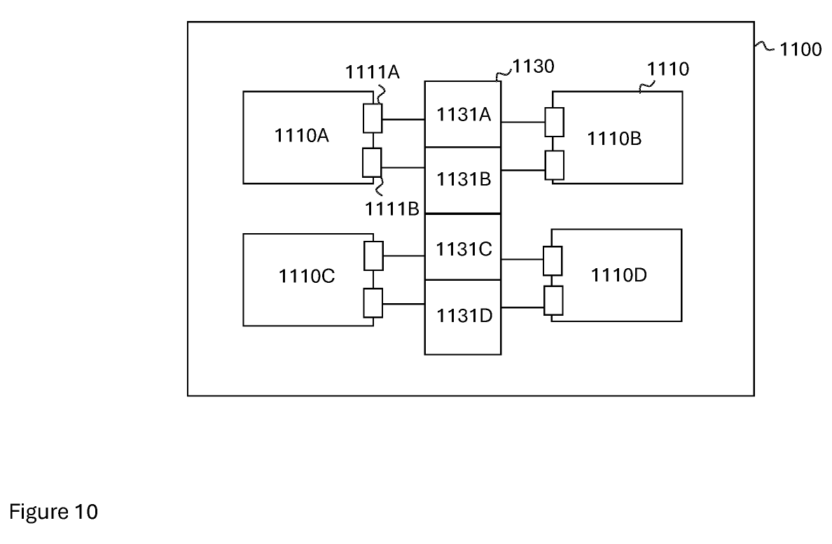

FIG. 10 illustrates another example SBU 1100. The SBU 1100 is similar in configuration to the SBU 100, and as such only the differences will be discussed in detail below. Corresponding components of SBU 100 have the corresponding reference numerals incremented by 1000. For convenience and clarity, and to better illustrate the relevant differences between the examples, some of the components of SBU 100 (e.g. the identifier assignment logic, memory controller and output ports) are not repeated in FIG. 10.

SBU 1100 differs from SBU 100 in that each memory unit 1110 comprises two egress ports 1111A and 1111B. Accordingly, the memory units 1110 are dual port memory units 1110, configured to handle two read requests simultaneously (i.e. in the same clock cycle), but outputting two read responses via respective ones of the two egress ports. In examples, the address space of the memory unit 1110 may be accessible by either egress port 1111, such that a response output via either port 1111 may comprise data stored anywhere in the memory unit 1110. In other examples, the memory unit 1110 may be partitioned such that only certain parts of the address space are accessible via the respective egress ports 1111.

The egress ports 1111 are connected to routing logic 1130 in a similar manner to the SBU 100 previously described, with the exception that each egress port 1111 is connected to a different level 1131 of the logic 1130. That is to say, a first egress port 1111A of unit 1110A is connected to the first level 1131A, but the second egress port 1111B is connected to the second level 1131B. Unit 1110B is similarly arranged on the opposite side of the logic 1130. Likewise, units 1110C and 1110D have egress ports connected respectively to the third level 1131C and fourth level 1131D.

Of course, other arrangements of the units 1110 are possible, so long as a pair of egress ports 1111 feed into each level 1131. For example, each unit 1110 may have both its ports 1111 connected to a particular level.

Herein the “logic” described is embodied in hardware. That is to say it comprises circuitry, for example comprising suitable logic gates or the like. Although for convenience the respective logic components of the SBU 100 have been described as separate components, they could be embodied by the same circuitry. This is particularly the case for the memory controller 120 and identifier assignment logic 140, which may be a single component.

Although implemented in hardware, in some examples the hardware logic is defined in a suitable hardware description language (HDL), such as Verilog or VHDL. Subsequently, a suitable synthesis tool (i.e. a suitable computer program running on a computer) may be employed to synthesise a netlist that describes the hardware logic, for example in terms of logic gates, flip-flops and other components. This netlist can then be used to generate suitable circuitry implementing the hardware logic. Example tools for synthesising HDL are well known, but may include Synopsys Design Compiler, Cadence Genus, Xilinx Vivado, and so on. Accordingly, in some examples the disclosure extends to a computer program in a hardware description language, which when executed by a synthesis tool, causes the generation of data representing a hardware circuit that implements any of the logic described in the present disclosure. The data representing the hardware circuit may be a netlist. The logic may comprise the shared memory device or subcomponents thereof, such as the identifier assignment logic and/or the routing logic.

Various modifications and alterations may be made to the examples discussed above within the scope of this disclosure. For example, it will be appreciated that the processing unit and processor described herein is merely one example of where the shared memory device can be employed. Such a device may be employed in a wide variety of situations where shared memory is required to be provided to multiple client devices.

In the discussion above, the memory controller causes the inactive banks to output dummy responses. In other examples, some other component (e.g. the index assignment logic or routing logic) may cause input to be provided that acts as a dummy response for the purpose of the sorting technique.

Whilst some of the above examples relate to ten memory units and six output ports, it will be understood that the teaching extends to any arbitrary number of memory units and output ports, so long as the output ports are equal to or less than the number of memory units.

Advantageously, the operation of the shared memory device is transparent to the client devices. That is to say, the routing logic and identifier assignment logic is not exposed to the client devices, that simply provide memory read requests to the shared memory device and receive responses via the appropriate port.

The examples described herein are to be understood as illustrative examples of embodiments of the invention. Further embodiments and examples are envisaged. Any feature described in relation to any one example or embodiment may be used alone or in combination with other features. In addition, any feature described in relation to any one example or embodiment may also be used in combination with one or more features of any other of the examples or embodiments, or any combination of any other of the examples or embodiments. Furthermore, equivalents and modifications not described herein may also be employed within the scope of the invention, which is defined in the claims.

1. A shared memory device, comprising:
a plurality of output ports, each output port configured for connection to a respective client device of a plurality of client devices;
a plurality of memory units, each memory unit comprising at least one egress port, wherein the number of egress ports comprised by the plurality of memory units is greater than or equal to the number of output ports;
routing logic connecting the egress ports to the output ports; and
hardware logic configured to:
receive at least one read request from a client device of the plurality of client devices, each read request comprising a memory address in one of the memory units;
identify each memory unit comprising a memory address that is present in a received read request as an active memory unit, and identify each memory unit not storing any memory address present in a received read request as an inactive memory unit;
cause each active memory unit to output, via its respective egress port, a memory read response comprising data stored at the memory address, and cause each inactive memory unit to output, via its respective egress port, a memory read response that is not responsive to any memory address specified in a received read request;
determine an identifier for each memory read response, wherein an identifier for a memory read response from an active memory unit is based on a desired output port for that memory read response;
include the identifier in each memory read response; and
provide each memory read response to the routing logic,
wherein the routing logic comprises a sequence of levels, a pair of egress ports being connected to each level, a final level in the sequence being connected to the output ports, each other level in the sequence providing input to a subsequent level of the sequence, and
wherein the routing logic is configured to route each memory read response from an active memory unit to a respective desired output port based on the identifiers.

2. The shared memory device of claim 1, wherein each level of the routing logic comprises at least one swap block comprising first and second inputs and first and second outputs, the swap block being configured to:
receive a first memory read response and a second memory read response at the first and second inputs respectively;
compare the identifier of the first memory read response with the identifier of the second memory read response;
in response to the identifier of the first memory read response being greater than the identifier of the second memory read response, output the first memory read response via the first output and the second memory read response via the second output; and
otherwise output the first memory read response via the second output and the second memory read response via the first output.

3. The shared memory device of claim 1, wherein the hardware logic determines an identifier for each memory read response from an active memory unit that is equal to an identifier of the desired output port.

4. The shared memory device of claim 2, wherein the hardware logic determines an identifier for each memory read response from an active memory unit that is equal to an identifier of the desired output port.

5. The shared memory device of claim 3, wherein the hardware logic determines an identifier for each memory read response from an inactive memory unit that corresponds to an unused output port or a dummy output port.

6. The shared memory device of claim 1, wherein the identifier is a unique integer in the range 0 to n-1, where n is the number of egress ports.

7. The shared memory device of claim 1, wherein the hardware logic is configured to remove the identifier from the memory read response before it egresses via the output port.

8. The shared memory device of claim 1, wherein the memory units are arranged in two columns, and the pair of egress ports connected to a level of the sequence of levels have corresponding positions in respective ones of the two columns.

9. The shared memory device of claim 8, wherein the routing logic is disposed between the two columns.

10. The shared memory device of claim 9, wherein each level of the routing logic is disposed between the pair of egress ports to which it is connected.

11. The shared memory device of claim 1, wherein the shared memory device is configured to receive the at least one read request and determine the identifiers in a first clock cycle, and cause the memory units to output the memory read responses, provide the memory read responses to the routing logic and route the or each memory response comprising data to the desired output port in a second clock cycle, the second clock cycle being immediately after the first clock cycle.

12. The shared memory device of claim 1, wherein each memory unit is a bank of static random access memory, SRAM.

13. A processing unit comprising:
a shared memory device comprising:
a plurality of output ports, each output port configured for connection to a respective client device of a plurality of client devices;
a plurality of memory units, each memory unit comprising at least one egress port, wherein the number of egress ports comprised by the plurality of memory units is greater than or equal to the number of output ports;
routing logic connecting the egress ports to the output ports; and
hardware logic configured to:
receive at least one read request from a client device of the plurality of client devices, each read request comprising a memory address in one of the memory units;
identify each memory unit comprising a memory address that is present in a received read request as an active memory unit, and identify each memory unit not storing any memory address present in a received read request as an inactive memory unit;
cause each active memory unit to output, via its respective egress port, a memory read response comprising data stored at the memory address, and cause each inactive memory unit to output, via its respective egress port, a memory read response that is not responsive to any memory address specified in a received read request;
determine an identifier for each memory read response, wherein an identifier for a memory read response from an active memory unit is based on a desired output port for that memory read response;
include the identifier in each memory read response; and
provide each memory read response to the routing logic, wherein the routing logic comprises a sequence of levels, a pair of egress ports being connected to each level, a final level in the sequence being connected to the output ports, each other level in the sequence providing input to a subsequent level of the sequence, and wherein the routing logic is configured to route each memory read response from an active memory unit to a respective desired output port based on the identifiers; and
accelerator hardware having multiple subcomponents, each subcomponent acting as a client device of the shared memory device.

14. A method carried out in a shared memory device, the shared memory device comprising:
a plurality of output ports, each output port connected to a respective client device of a plurality of client devices;
a plurality of memory units, each memory unit comprising at least one egress port, wherein the number of egress ports comprised by the plurality of memory units is greater than or equal to the number of output ports; and
routing logic connecting the egress ports to the output ports;
the method comprising:
receiving at least one read request from a client device of the plurality of client devices, each read request comprising a memory address in one of the memory units;
identifying each memory unit storing a memory address that is present in a received read request as an active memory unit, and identifying each memory unit not storing any memory address present in a received read request as an inactive memory unit;
causing each active memory unit to output, via its respective egress port, a memory read response comprising data stored at the memory address, and causing each inactive memory unit to output, via its respective egress port, a memory read response that is not responsive to any memory address specified in a received read request;
determining an identifier for each memory read response, wherein an identifier for a memory read response from an active memory unit is based on a desired output port for that memory read response;
including the identifier in each memory read response;
providing each memory read response to the routing logic; and
routing, by the routing logic, each memory read response from an active memory unit to a respective desired output port based on the identifiers;
wherein the routing logic comprises a sequence of levels, a pair of egress ports being connected to each level, a final level in the sequence being connected to the output ports, each other level in the sequence providing input to a subsequent level of the sequence.

15. The method of claim 14, wherein the identifier is a unique integer in the range 0 to n-1, where n is the number of egress ports.

16. The method of claim 14, wherein the hardware logic is configured to remove the identifier from the memory read response before it egresses via the output port.

17. The method of claim 14, wherein the memory units are arranged in two columns, and the pair of egress ports connected to a level of the sequence of levels have corresponding positions in respective ones of the two columns.

18. A non-transitory computer readable medium comprising instructions in a hardware description language, which when executed by a computer, cause the computer to generate data representing hardware circuitry that implements:
a plurality of output ports, each output port configured for connection to a respective client device of a plurality of client devices;
a plurality of memory units, each memory unit comprising at least one egress port, wherein the number of egress ports comprised by the plurality of memory units is greater than or equal to the number of output ports;
routing logic connecting the egress ports to the output ports; and
hardware logic configured to:
receive at least one read request from a client device of the plurality of client devices, each read request comprising a memory address in one of the memory units;
identify each memory unit comprising a memory address that is present in a received read request as an active memory unit, and identify each memory unit not storing any memory address present in a received read request as an inactive memory unit;
cause each active memory unit to output, via its respective egress port, a memory read response comprising data stored at the memory address, and cause each inactive memory unit to output, via its respective egress port, a memory read response that is not responsive to any memory address specified in a received read request;
determine an identifier for each memory read response, wherein an identifier for a memory read response from an active memory unit is based on a desired output port for that memory read response;
include the identifier in each memory read response; and
provide each memory read response to the routing logic;
wherein the routing logic comprises a sequence of levels, a pair of egress ports being connected to each level, a final level in the sequence being connected to the output ports, each other level in the sequence providing input to a subsequent level of the sequence, and
wherein the routing logic is configured to route each memory read response from an active memory unit to a respective desired output port based on the identifiers.

19. The non-transitory computer readable medium of claim 18, wherein the shared memory device is configured to receive the at least one read request and determine the identifiers in a first clock cycle, and cause the memory units to output the memory read responses, provide the memory read responses to the routing logic and route the or each memory response comprising data to the desired output port in a second clock cycle, the second clock cycle being immediately after the first clock cycle.

20. The non-transitory computer readable medium of claim 18, wherein each memory unit is a bank of static random access memory, SRAM.
